(19) United States
(12) Patent Application Publication
(10) Pub. No.: US 2026/0081621 A1
(43) Pub. Date: Mar. 19, 2026

(54) LAYERED DECODING OF LOW DENSITY PARITY CHECK (LDPC) CODES

(71) Applicant: Samsung Electronics Co., Ltd., Suwon-si (KR)

(72) Inventors: Heping Wan, Plano, TX (US); Joonyoung Cho, Portland, OR (US); Min Jang, Suwon-si (KR)

(21) Appl. No.: 19/229,503

(22) Filed: Jun. 5, 2025

Related U.S. Application Data
(60) Provisional application No. 63/695,795, filed on Sep. 17, 2024.
(60) Provisional application No. 63/695,985, filed on Sep. 18, 2024.

(51) Int. Cl. H03M 13/11; H03M 13/37; H03M 13/43; H04L 1/00

(52) U.S. Cl. CPC H03M 13/114; H03M 13/3746; H03M 13/43; H04L 1/005; H04L 1/0057

(57) ABSTRACT

Layered decoding of low-density parity check (LDPC) codes are decoded by selecting one or more of a plurality of check nodes (CNs) based on degree in priority, where the degree in priority for each of the plurality of CNs is based on a number of variable nodes (VNs) connected to the respective CN. Layered decoding for an LDPC code is performed based on applying a sum-product algorithm and an approximated sum-product algorithm. The sum-product algorithm is applied to at least some of the selected one or more CNs among the plurality of CNs. The approximated sum-product algorithm is applied to one or more remaining CNs, other than the selected one or more CNs, among the plurality of CNs.

### CROSS-REFERENCE TO RELATED AND CLAIM OF PRIORITY

The present application claims priority under 35 U.S.C. § 119 (e) to U.S. Provisional Patent Application No. 63/695,795 filed on Sep. 17, 2024 and U.S. Provisional Patent Application No. 63/695,985 filed on Sep. 18, 2024, which are hereby incorporated by reference in their entirety.

### TECHNICAL FIELD

The present disclosure relates generally to low density parity check codes and, more specifically, to achieving a good trade-off between the complexity and the performance in the layered decoding for low density parity check codes.

### BACKGROUND

Wireless communication has been one of the most successful innovations in modern history. Recently, the number of subscribers to wireless communication services exceeded five billion and continues to grow quickly. The demand of wireless data traffic is rapidly increasing due to the growing popularity among consumers and businesses of smart phones and other mobile data devices, such as tablets, “note pad” computers, net books, eBook readers, and machine type of devices. In order to meet the high growth in mobile data traffic and support new applications and deployments, improvements in radio interface efficiency and coverage are of paramount importance. To meet the demand for wireless data traffic having increased since deployment of 4G communication systems, and to enable various vertical applications, 5G communication systems have been developed and are currently being deployed.

### SUMMARY

The present disclosure relates to layered decoding of low density parity check codes by selectively applying a sum-product algorithm and an approximated sum-product algorithm to CNs.

In a first embodiment, a method for decoding LDPC codes in a communication system includes selecting one or more of a plurality of CNs based on degree in priority, where the degree in priority for each of the plurality of CNs is based on a number of VNs connected to the respective CN. The method also includes performing layered decoding for an LDPC code based on applying a sum-product algorithm and an approximated sum-product algorithm. The method further includes applying the sum-product algorithm to at least some of the selected one or more CNs among the plurality of CNs. The method still further includes applying the approximated sum-product algorithm to one or more remaining CNs, other than the selected one or more CNs, among the plurality of CNs.

In a second embodiment, an apparatus for decoding LDPC codes in a communication system includes a transceiver configured to receive a signal having an associated LDPC code, and at least one processor coupled to the transceiver and configured to decode the LDPC code. The at least one processor is configured to decode the LDPC code by selecting one or more of a plurality of CNs based on degree in priority, where the degree in priority for each of the plurality of CNs is based on a number of VNs connected to the respective CN. The at least one processor is also configured to decode the LDPC code by performing layered decoding for the LDPC code based on applying a sum-product algorithm and an approximated sum-product algorithm. The at least one processor is further configured to decode the LDPC code by applying the sum-product algorithm to at least some of the selected one or more CNs among the plurality of CNs. The at least one processor is still further configured to decode the LDPC code by applying the approximated sum-product algorithm to one or more remaining CNs, other than the selected one or more CNs, among the plurality of CNs.

In yet another embodiment, a non-transitory machine readable medium includes instructions that, when executed by at least one processor of an electronic device, cause the electronic device to decode LDPC codes in a communication system. The instructions cause the at least one processor of the electronic device to select one or more of a plurality of check nodes (CNs) based on degree in priority, where a degree in priority for each of the plurality of CNs is based on a number of variable nodes (VNs) connected to the respective CN. The instructions also cause the at least one processor of the electronic device to perform layered decoding for the LDPC code based on applying a sum-product algorithm and an approximated sum-product algorithm. The instructions further cause the at least one processor of the electronic device to applying the sum-product algorithm and the approximated sum-product algorithm by: applying the sum-product algorithm to at least some of the selected one or more CNs among the plurality of CNs; and applying the approximated sum-product algorithm to one or more remaining CNs, other than the selected one or more CNs, among the plurality of CNs, the apparatus comprising:

Any single one or any combination of the following features may be used with any of the first, second, or third embodiments. The approximated sum-product algorithm may include a min-sum algorithm. Selecting the one or more of the plurality of CNs based on degree in priority may include selecting CNs among the plurality of CNs that have with low degrees in priority, where the low degree in priority is based on being less than a specified priority threshold. The specified priority threshold may be a fixed number of edges involved in applying the sum-product algorithm. Selecting the one or more of the plurality of CNs based on degree in priority may exclude shortened VNs before determining a degree in priority for each of the plurality of CNs. Selecting the one or more of a plurality of check nodes (CNs) based on degree in priority may include selecting, from among the plurality of CNs, at least one CN having a largest number of punctured VNs connected to the respective CN.

Any single one or any combination of the following features may be used with the third embodiment. The approximated sum-product algorithm may include a min-sum algorithm. Selecting the one or more of the plurality of CNs based on degree in priority may include selecting CNs among the plurality of CNs that have with low degrees in priority, where the low degree in priority is based on being less than a specified priority threshold. The specified priority threshold may be a fixed number of edges involved in applying the sum-product algorithm. Selecting the one or more of the plurality of CNs based on degree in priority may exclude shortened VNs before determining a degree in priority for each of the plurality of CNs. Selecting the one or more of a plurality of check nodes (CNs) based on degree in priority may include selecting, from among the plurality of CNs, at least one CN having a largest number of punctured VNs connected to the respective CN.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network within which layered LDPC decoding selectively applying SPA and simplified SPA to check nodes may be implemented according to embodiments of the present disclosure;

FIG. 2 illustrates an example gNB within which layered LDPC decoding selectively applying SPA and simplified SPA to check nodes may be implemented according to embodiments of the present disclosure;

FIG. 3 illustrates an example UE 116 within which layered LDPC decoding selectively applying SPA and simplified SPA to check nodes may be implemented according to embodiments of the present disclosure;

FIG. 4A and FIG. 4B illustrate an example of wireless transmit and receive paths, respectively, within the gNB of FIG. 2 and/or the UE of FIG. 3;

FIG. 5 illustrates a flowchart of a process for layered LDPC decoding selectively applying SPA and simplified SPA to check nodes according to embodiments of the present disclosure;

FIG. 6 illustrates a flowchart of an example procedure for performing an iteration of layered LDPC decoding selectively applying SPA and simplified SPA to check nodes according to embodiments of the present disclosure;

FIG. 7 illustrates a flowchart of an example procedure for creating a subset of CNs to which SPA is applied based on degree of priority during an iteration of layered LDPC decoding according to embodiments of the present disclosure;

FIG. 8 illustrates a flowchart of an example procedure for creating a subset of CNs to which SPA is applied based on degree of priority while consideration puncturing during an iteration of layered LDPC decoding according to embodiments of the present disclosure;

FIG. 9 illustrates a flowchart of an alternative example procedure for performing an iteration of layered LDPC decoding selectively applying SPA and simplified SPA to check nodes while considering shortening according to embodiments of the present disclosure;

FIG. 10 illustrates a flowchart of another alternative example procedure for creating a subset of CNs to which SPA is applied based on degree of priority during an iteration of layered LDPC decoding, with consideration of shortening, according to embodiments of the present disclosure;

FIG. 11 illustrates a flowchart of still another alternative example procedure for creating a subset of CNs to which SPA is applied based on degree of priority during an iteration of layered LDPC decoding, with consideration of both shortening and puncturing, according to embodiments of the present disclosure;

FIG. 12A illustrates comparisons between simulations of layered decoding of low-density parity check codes using only SPA and using a combination of SPA and MSA in accordance with the present disclosure;

FIG. 12B illustrates simulations of the ratio of reduction in hyperbolic function as a function of information size achieved by selectively applying SPA and simplified SPA to check nodes according to embodiments of the present disclosure; and

FIG. 13 illustrates an example parity check matrix and FIGS. 13A through 13C illustrate processing of check nodes CNs for a single iteration of layered decoding of the parity check matrix of FIG. 13 in a natural order.

### DETAILED DESCRIPTION

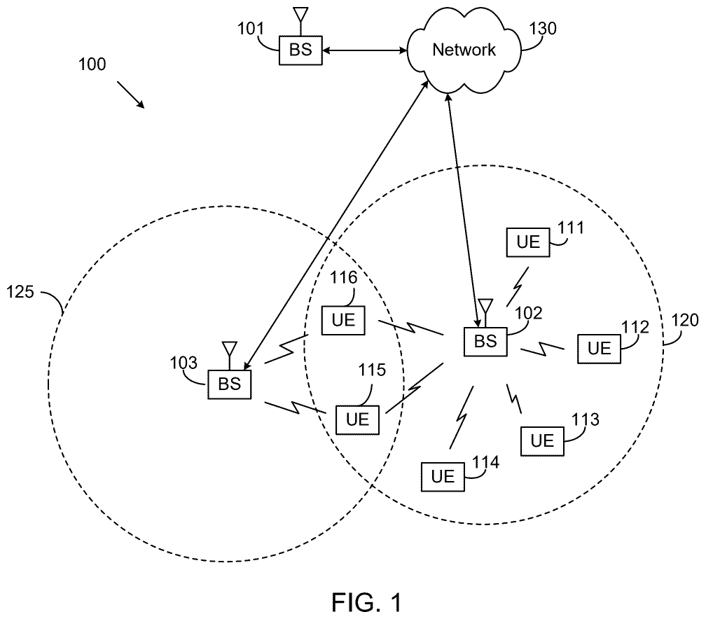

FIGS. 1-12B, discussed below, and the various, non-limiting embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Low-density parity-check (LDPC) codes have been widely applied to wireless communications because LDPC codes are able to approach channel capacity asymptotically using belief propagation (BP) decoding. A LDPC code of dimension K and code length N are defined by the (N−K)× N parity check matrix (PCM) H, where each row and each column correspond to a check equation and a codeword bit, respectively. Denote h_{j,i} ∈{0,1} the element in j-th row and i-th column of PCM, where j∈{0,1, . . . , N−K−1} and i∈{0,1, . . . , N−1}.

A LDPC code of dimension K and code length N are defined by the parity check matrix (PCM) H_{(N-K)×N}. A valid LDPC codeword v={v₀, v₁, . . . , v_{N-1}} must satisfy H_{(N-K)×N}×v^{T}=0_{(N-K)×1}—that is, v must satisfy N−K check equations, each of which corresponds to a row of H. One example of an (N=10, K=5) LDPC code is:

$$H = [ \begin{matrix}1 & 1 & 1 & 1 & 0 & 0 & 0 & 0 & 0 & 0 \\ 1 & 0 & 0 & 0 & 1 & 1 & 1 & 0 & 0 & 0 \\ 0 & 1 & 0 & 0 & 1 & 0 & 0 & 1 & 1 & 0 \\ 0 & 0 & 1 & 0 & 0 & 1 & 0 & 1 & 0 & 1 \\ 0 & 0 & 0 & 1 & 0 & 0 & 1 & 0 & 1 & 1\end{matrix} ] .$$

Each row of the above example parity check matrix H is v={v₀, v₁, v₂, v₃, v₄, v₅, v₆, v₇, v₈, v₉}. Note that, for example, v₀⊕v₁⊕v₂⊕v₃=0 for the first row, and v₃⊕v₆⊕v₈⊕v₈⊕v₉=0 for the last row. Similar statements can be written for the remaining rows.

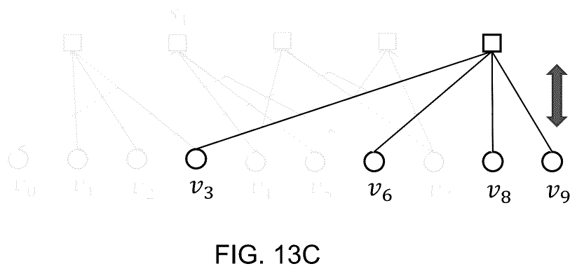

As shown in FIG. 13, LDPC codes can also be represented by the Tanner graph (where the example in FIG. 13 corresponds to the example parity check matrix H above), which is composed of two types of nodes, called check node (CN) and variable node (VN). The VN i is connected to the CN j, whenever h_{j,i}=1. A CN and a VN are neighbors whenever the Cn and the VN are connected. Accordingly, in a Tanner graph, there are (N−K) CNs, one for each check equation, and N VNs, one for each codeword bit. There exists an edge connection between CN j and VN i whenever h_{j,i}=1. There exists a one-to-one mapping between a particular parity check matrix and the counterpart Tanner graph.

In layered decoding [1], CNs are processed in a given order instead of in parallel. Layered decoding is fulfilled by iteratively exchanging log likelihood ratios (LLRs) between CNs and VNs that are neighbors. The messages that can be updated in a Tanner graph include: a posteriori LLRs (AP-LLRs) λᵢ at VN i; variable-to-check (V2C) message α_{i→j}, which is the message passed from VN i to (neighboring) CN j; and check-to-variable (C2V) message β_{j→i}, which is the message passed from CN j to (neighboring) VN i. FIGS. 13A through 13C illustrate processing of the CNs for a single iteration of layered decoding of the parity check matrix of FIG. 13 in a natural order. FIG. 13A illustrates messages exchanged when j=0 for a particular iteration, and FIG. 13B illustrates messages exchanged when j=1 for that iteration. The messaging when j=2 and when j=3 is omitted for simplicity and clarity, but the messaging when j=4 is illustrated in FIG. 13C. From FIG. 13C, layered decoding returns to FIG. 13A for the next iteration.

Belief propagation (BP) decoding is essential for the successful implementation of LDPC codes. BP iteratively updates the following messages: α_{i→j}, the variable-to-check (V2C) message passed from the VN i to a neighboring CN j; β_{j→i}, the check-to-variable message (C2V) passed from the CN j to a neighboring VN i; and γᵢ, the a posteriori message for the VN i. Other notations that may be used herein include:

$$\cdot {𝒱}_{j} = \{ VN indices connected to CN j \} , e . g . , {𝒱}_{0} = \{ 0 , 1 , 2 , 3 \} for FIG . 13 ;$$

$$\cdot {𝒱}_{j \backslash i} = \{ VN indices connected to CN j \} - \{ i \} , e . g . , {𝒱}_{0 \backslash 1} = \{ 0 , 2 , 3 \} for FIG . 13 ;$$

$$\cdot {j}_{} = \{ VN indices connected to VN i \} , e . g . , {1}_{} = \{ 0 , 2 \} for FIG . 13 ;$$

$$and$$

$$\cdot {i \backslash j}_{} = \{ CN indices connected to VN i \} - \{ j \} , e . g . , {1 \backslash 0}_{} = \{ 2 \} for FIG . 13.$$

Conventionally, BP decoding is equipped with flooding schedule, where all VNs update the V2C messages and all CNs update the C2V messages in parallel. However, the flooding schedule may require numerous iterations to achieve a desired block error rate (BLER) due to its slow convergence speed. This issue can be mitigated by using layered decoding, which reduces the necessary number of iterations by half. In each iteration of layered decoding, the messages are updated in a CN-by-CN manner, ensuring that the latest messages are immediately exploited by the succeeding CNs and resulting in a faster convergence speed.

To implement LDPC in practical communication systems, the complexity of LDPC coding should be reduced such that the throughput is improved.

Exact calculation of the C2V message β_{j→i} for CN sⱼ and VN vᵢ rely on the sum-product algorithm (SPA):

$${β}_{j \to i} = 2 tan {h}^{- 1} ( {\prod }_{{i}^{′} ∈ {𝒱}_{j \backslash i}} tan h ( {α}_{{i}^{′} \to j} ) ) .$$

Although SPA offers excellent performance, implementation is challenging due to the necessity of hyperbolic functions including high-complexity operations such as exponential and logarithmic computations. Some algorithms may attempt to simplify SPA, invariably at the cost of performance loss. The most well-known simplified SPA is the min-sum algorithm (MSA), the implementation of which is simple since the required operations are comparison and addition:

$${β}_{j \to i} = ( {\prod }_{{i}^{′} ∈ {𝒱}_{j \backslash i}} sgn ( {α}_{{i}^{′} \to j} ) ) \times {min}_{{i}^{′} ∈ {𝒱}_{j ∖ i}} \vert {α}_{{i}^{′} \to j} \vert .$$

As an approximation of SPA, MSA is simple but leads to inaccurate calculation and hence performance loss. To take the advantage of both excellent performance and low complexity, the present disclosure applies both SPA and MSA to carefully selected CNs during layered decoding.

The present disclosure achieves a good trade-off between complexity and performance in layered decoding for LDPC codes by applying the min-sum algorithm and the sum-product algorithm to different check nodes. Layered decoding is provided for one or more LDPC codes based on applying a sum-product algorithm and an approximated sum-product algorithm (e.g., a min-sum algorithm) to one or more different check nodes. That is, the overall mechanism reduces complexity of layered decoding by applying SPA and approximated SPA (e.g., MSA) to different CNs. One or more CNs with low degrees in priority are selected, where a degree of a particular CN is a number of VNs connected to the particular CN. In combination with selected CNs with low degrees in priority, one or both of shortened VNs and punctured VNs may be exploited. For shortened VNs, determination of the CN degree in priority may exclude shortened VNs. For punctured VNs, after determination of the CN degree in priority, CNs connected to a large number of punctured VNs may be selected first.

The following documents and standards descriptions are hereby incorporated by reference into the present disclosure as if fully set forth herein:
[1] Hocevar, Dale E. “A reduced complexity decoder architecture via layered decoding of LDPC codes.” IEEE Workshop on Signal Processing Systems, 2004.

FIGS. 1-4 below describe various embodiments implemented in wireless communications systems and with the use of orthogonal frequency division multiplexing (OFDM) or orthogonal frequency division multiple access (OFDMA) communication techniques. The descriptions of FIGS. 1-4 are not meant to imply physical or architectural limitations to how different embodiments may be implemented. Different embodiments of the present disclosure may be implemented in any suitably arranged communications system.

FIG. 1 illustrates an example wireless network 100 within which layered LDPC decoding selectively applying SPA and simplified SPA to check nodes may be implemented according to embodiments of the present disclosure. The embodiment of the wireless network 100 shown in FIG. 1 is for illustration only. Other embodiments of the wireless network 100 could be used without departing from the scope of this disclosure.

As shown in FIG. 1, the wireless network 100 includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

The dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof for decoding of low-density parity check codes. In certain embodiments, one or more of the BSs 101-103 include circuitry, programing, or a combination thereof to support LDPC decoding.

Although FIG. 1 illustrates one example of a wireless network, various changes may be made to FIG. 1. For example, the wireless network 100 could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

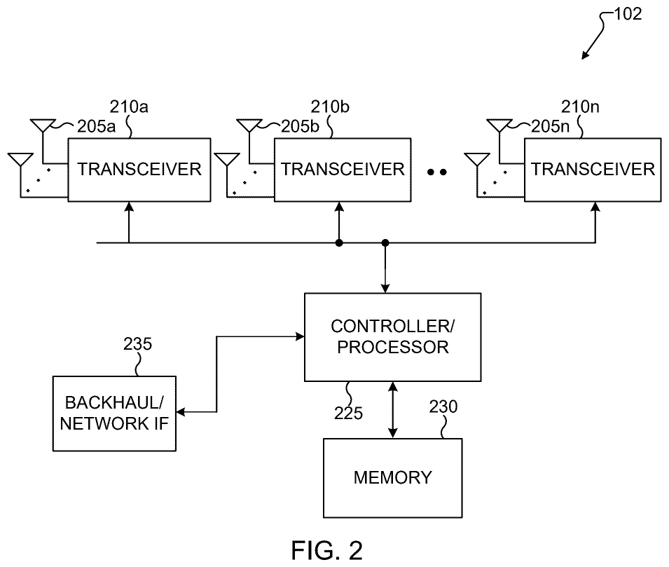

FIG. 2 illustrates an example gNB 102 within which layered LDPC decoding selectively applying SPA and simplified SPA to check nodes may be implemented according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming radio frequency (RF) signals, such as signals transmitted by UEs in the wireless network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of uplink (UL) channel signals and the transmission of downlink (DL) channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. As another example, the controller/processor 225 could support methods for beam management in JPTA system with multiple component carriers. Any of a wide variety of other functions could be supported in the gNB 102 by the controller/processor 225.

The controller/processor 225 is also capable of executing programs and other processes resident in the memory 230, such as processes to trigger beam management in JPTA system with multiple component carriers. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

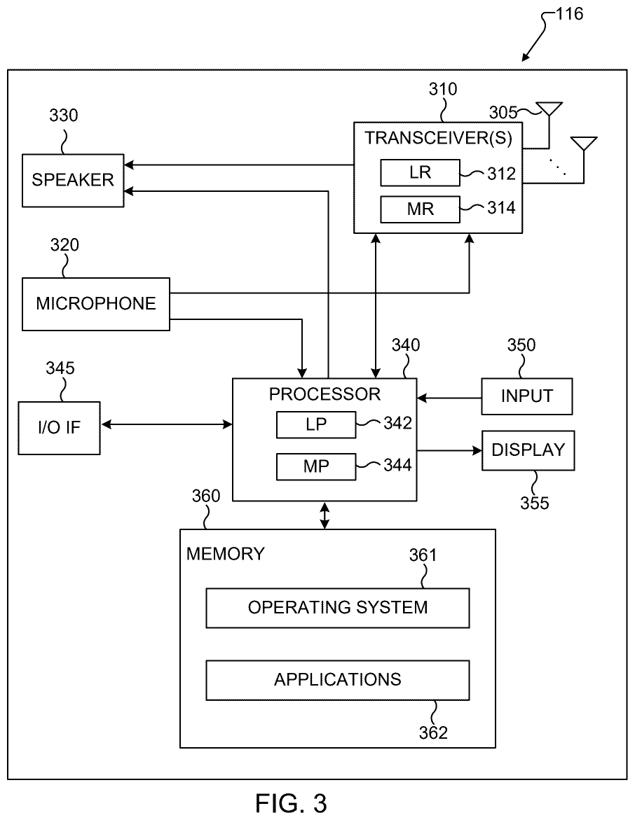

FIG. 3 illustrates an example UE 116 within which layered LDPC decoding selectively applying SPA and simplified SPA to check nodes may be implemented according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna(s) 305, an incoming RF signal transmitted by a gNB of the wireless network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. For example, the processor 340 may execute processes for beam management in JPTA system with multiple component carriers as described in embodiments of the present disclosure. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes, for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

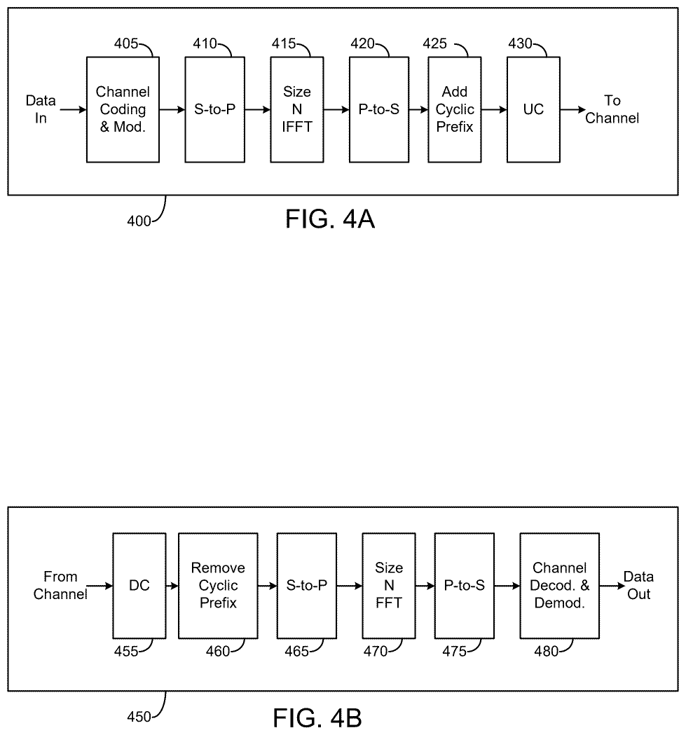

FIG. 4A and FIG. 4B illustrate an example of wireless transmit and receive paths 400 and 450, respectively, according to embodiments of the present disclosure. For example, a transmit path 400 may be described as being implemented in a gNB (such as gNB 102), while a receive path 450 may be described as being implemented in a UE (such as UE 116). However, it will be understood that the receive path 450 can be implemented in a gNB and that the transmit path 400 can be implemented in a UE. In some embodiments, the receive path 450 is configured for decoding of low-density parity check codes as described in embodiments of the present disclosure. For example, embodiments of LDPC decoding as described herein may be implemented in connection with channel decoding and demodulation 480 depicted in FIG. 4B.

As illustrated in FIG. 4A, the transmit path 400 includes a channel coding and modulation block 405, a serial-to-parallel (S-to-P) block 410, a size N Inverse Fast Fourier Transform (IFFT) block 415, a parallel-to-serial (P-to-S) block 420, an add cyclic prefix block 425, and an up-converter (UC) 430. The receive path 450 includes a down-converter (DC) 455, a remove cyclic prefix block 460, a S-to-P block 465, a size N Fast Fourier Transform (FFT) block 470, a parallel-to-serial (P-to-S) block 475, and a channel decoding and demodulation block 480.

In the transmit path 400, the channel coding and modulation block 405 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 410 converts (such as de-multiplexes) the serial modulated symbols to parallel data in order to generate N parallel symbol streams, where N is the IFFT/FFT size used in the gNB 102 and the UE 116. The size N IFFT block 415 performs an IFFT operation on the N parallel symbol streams to generate time-domain output signals. The parallel-to-serial block 420 converts (such as multiplexes) the parallel time-domain output symbols from the size N IFFT block 415 in order to generate a serial time-domain signal. The add cyclic prefix block 425 inserts a cyclic prefix to the time-domain signal. The up-converter 430 modulates (such as up-converts) the output of the add cyclic prefix block 425 to a RF frequency for transmission via a wireless channel. The signal may also be filtered at a baseband before conversion to the RF frequency.

As illustrated in FIG. 4B, the down-converter 455 down-converts the received signal to a baseband frequency, and the remove cyclic prefix block 460 removes the cyclic prefix to generate a serial time-domain baseband signal. The serial-to-parallel block 465 converts the time-domain baseband signal to parallel time-domain signals. The size N FFT block 470 performs an FFT algorithm to generate N parallel frequency-domain signals. The (P-to-S) block 475 converts the parallel frequency-domain signals to a sequence of modulated data symbols. The channel decoding and demodulation block 480 demodulates and decodes the modulated symbols to recover the original input data stream.

Each of the gNBs 101-103 may implement a transmit path 400 that is analogous to transmitting in the downlink to UEs 111-116 and may implement a receive path 450 that is analogous to receiving in the uplink from UEs 111-116. Similarly, each of UEs 111-116 may implement a transmit path 400 for transmitting in the uplink to gNBs 101-103 and may implement a receive path 450 for receiving in the downlink from gNBs 101-103.

Each of the components in FIGS. 4A and 4B can be implemented using only hardware or using a combination of hardware and software/firmware. As a particular example, at least some of the components in FIGS. 4A and 4B may be implemented in software, while other components may be implemented by configurable hardware or a mixture of software and configurable hardware. For instance, the FFT block 470 and the IFFT block 415 may be implemented as configurable software algorithms, where the value of size N may be modified according to the implementation.

Furthermore, although described as using FFT and IFFT, this is by way of illustration only and should not be construed to limit the scope of the present disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 4A and 4B illustrate examples of wireless transmit and receive paths 400 and 450, respectively, various changes may be made to FIGS. 4A and 4B. For example, various components in FIGS. 4A and 4B can be combined, further subdivided, or omitted and additional components can be added according to particular needs. Also, FIGS. 4A and 4B are meant to illustrate examples of the types of transmit and receive paths that can be used in a wireless network. Any other suitable architectures can be used to support wireless communications in a wireless network.

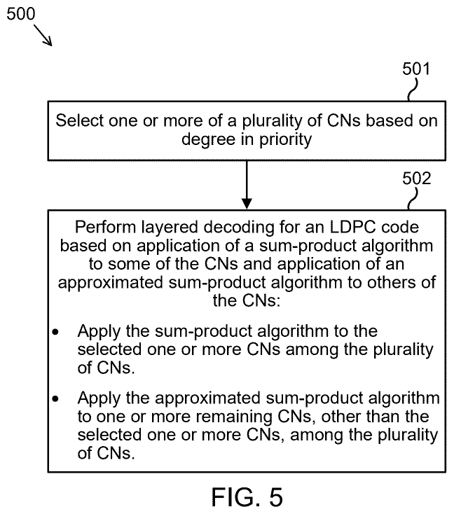

FIG. 5 illustrates a flowchart of a process 500 for layered LDPC decoding selectively applying SPA and simplified SPA to check nodes according to embodiments of the present disclosure. For example, the process 500 for layered decoding of low-density parity check codes can be performed by the UE 116, the gNB 102, and/or network 130 in the wireless network 100 of FIG. 1. This example is for illustration only and other embodiments can be used without departing from the scope of the present disclosure.

The example process 500 of FIG. 5 for decoding LDPC codes in a communication system begins with selecting one or more of a plurality of CNs based on degree in priority (step 501). The degree in priority for each of the plurality of CNs is based on a number of VNs connected to the respective CN. In some embodiments, the selection of one or more of a plurality of CNs based on degree in priority may also take into account shortening, puncturing, or both.

Layered decoding for a LDPC code is then performed based on application of a sum-product algorithm to some of the CNs and application of an approximated sum-product algorithm to others of the CNs (step 502). The sum-product algorithm is applied to at least some of the selected one or more CNs among the plurality of CNs. The approximated sum-product algorithm is applied to one or more remaining CNs, other than the selected one or more CNs, among the plurality of CNs. In some embodiments, shortening may be taken into account when applying the sum-product algorithm to the selected one or more CNs, such that the sum-product algorithm is applied only to C2V messages for non-shortened VNs connected to the respective CN, while the approximated sum-product algorithm applied to C2V messages for non-shortened VNs connected to the that CN.

Although FIG. 5 illustrates one example of a process 500 for LDPC decoding, various changes may be made to FIG. 5. For example, while shown as a series of steps, various steps in FIG. 5 could overlap, occur in parallel, occur in a different order, or occur any number of times (including zero times).

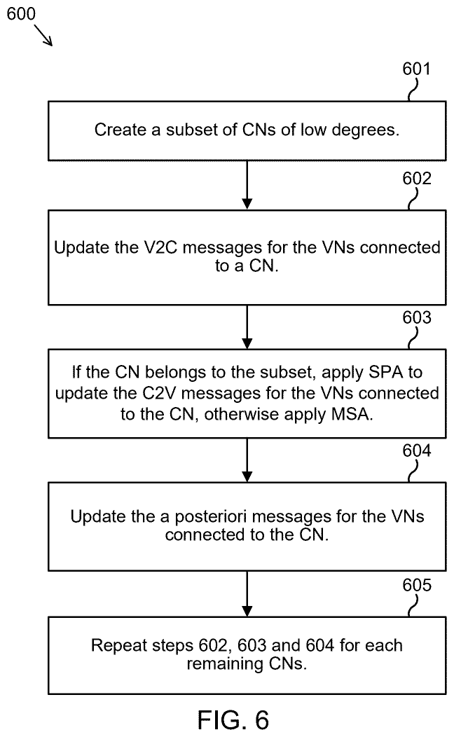

FIG. 6 illustrates a flowchart of an example procedure 600 for an iteration of layered LDPC decoding selectively applying SPA and simplified SPA to check nodes according to embodiments of the present disclosure. For example, procedure 600 for layered decoding of low-density parity check codes can be performed by the UE 116, the gNB 102, and/or network 130 in the wireless network 100 of FIG. 1. This example is for illustration only and other embodiments can be used without departing from the scope of the present disclosure.

For the sake of simplicity, FIG. 6 presents the operations concerning the message updates in one iteration for a first CN, which can be generalized to other iterations for the remaining CNs. Let [symbol] and [symbol] denote the set of the VNs connected to the CN j and the set of the CNs connected to the VN i, respectively. [symbol] and [symbol] denote [symbol] excluding the VN i and [symbol] excluding the CN j, respectively. The C2V messages {β_{j→i}: (j,i)∈{0, 1, . . . , N−K−1}× {0, 1, . . . , N−1}} are initialized to zeros and the a posteriori messages {γᵢ: i∈{0, 1, . . . , N−1}} are initialized according to the channel observations.

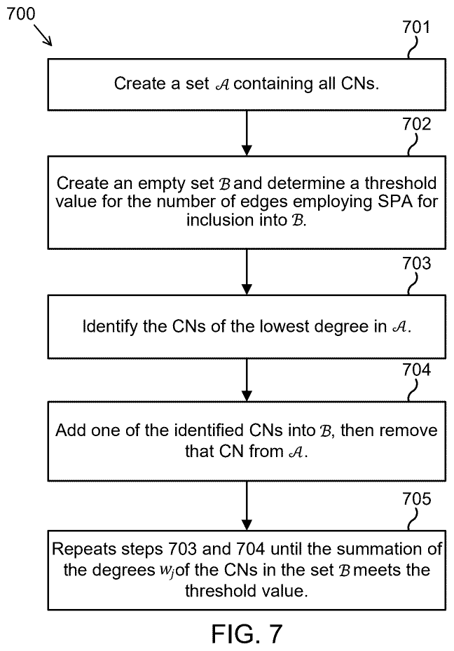

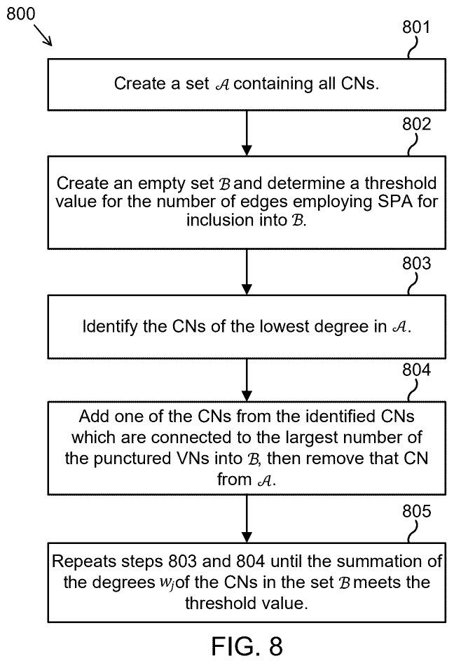

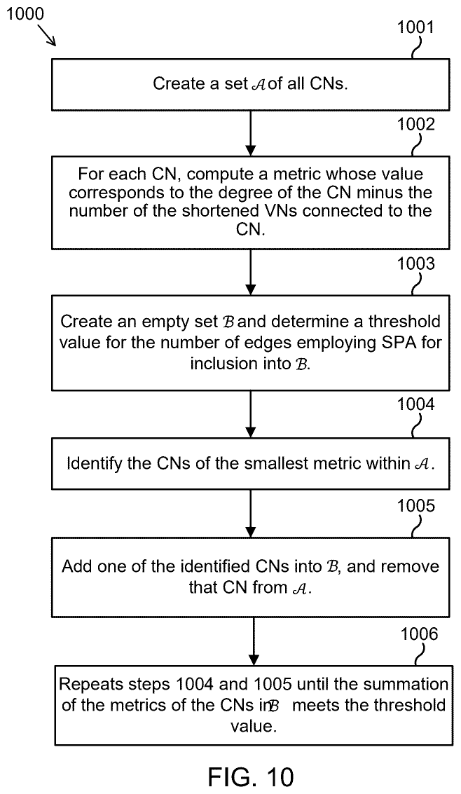

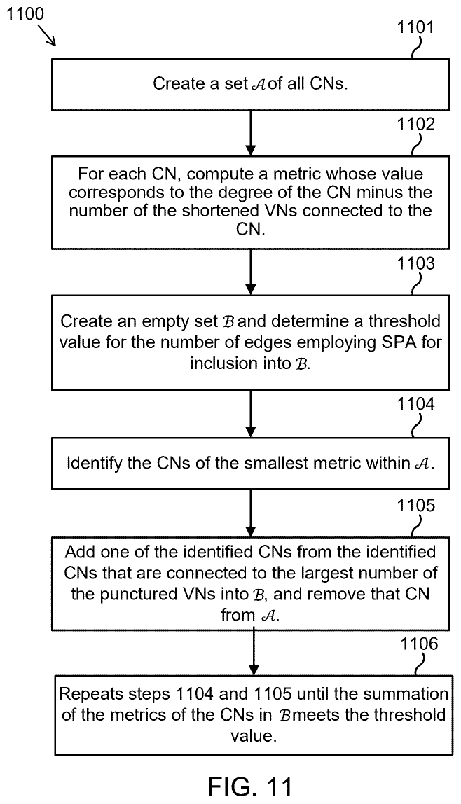

The procedure 600 begins with a subset, denoted [symbol] , of CNs being created (step 601), for which SPA is used to calculate the C2V messages. In selecting CNs to form the subset B, priority is given to those CNs with fewer neighboring VNs. By doing so, SPA can be applied to more CNs, meaning that MSA can be applied to fewer CNs, under the restriction of a fixed number of edges utilizing SPA. This allows for mitigating the performance degradation caused by the use of MSA. Embodiments of creating the set B are described below in connection with FIGS. 7, 8, 10, and 11: FIG. 7 discloses creating the set B based on degree of priority. FIG. 8 discloses creating the set B based on degree of priority and additionally considering puncturing. FIG. 10 discloses creating the set [symbol] based on degree of priority and considering shortening. FIG. 11 discloses creating the set [symbol] based on degree of priority and additionally considering both puncturing and shortening.

In one iteration of the layered decoding, CNs can be processed sequentially. Processing one of CNs j refers to the message updates according to steps 602, 603, and 604. However, the order of processing CNs is not limited in the present disclosure.

Based on the latest γᵢ and β_{j→i}, the V2C messages passed from the VNs neighboring the CN j to the CN j are updated (step 602) as follows:

$${α}_{i \to j} ← {γ}_{i} - {β}_{j \to i} for i ∈ {𝒱}_{j} .$$

Based on the received V2C messages from the neighboring VNs, the CN j updates the C2V messages and pass those messages back to the neighboring VNs. If the CN j belongs to the set B, SPA is used to compute the C2V messages (step 603) as follows:

$${β}_{j \to i} ← \{ \begin{matrix}2 \times tan {h}^{- 1} ( {\prod }_{{i}^{′} ∈ {𝒱}_{j \backslash i}} tan h ( \frac{{α}_{{i}^{′} \to j}}{2} ) ) , & j ∈ ℬ \\ ( {\prod }_{{i}^{′} ∈ {𝒱}_{j \backslash i}} sgn ( {α}_{{i}^{′} \to j} ) ) \times {min}_{{i}^{′} ∈ {𝒱}_{j ∖ i}} \vert {α}_{{i}^{′} \to j} \vert , & j ∉ {ℬ}^{c}\end{matrix} , for i ∈ {𝒱}_{j}$$

Otherwise a simplified SPA (e.g., MSA, although the present disclosure is not limited to MSA) is used to compute the C2V messages.

Based on the updated C2V messages from the CN j, the a posteriori messages for the VNs V are updated (step 604) as follows:

$${γ}_{i} ← {α}_{i \to j} + {β}_{j \to i} for i ∈ {𝒱}_{j} .$$

The latest γᵢ and β_{j→i} will be used to process next CN. The operations in steps 602, 603 and 604 are repeated (step 605) for each of CNs. The updated messages from the processing of current CN can be immediately applied to process next CN, which therefore speeds up the convergence.

Although FIG. 6 illustrates one example of a procedure 600 for LDPC decoding, various changes may be made to FIG. 6. For example, while shown as a series of steps, various steps in FIG. 6 could overlap, occur in parallel, occur in a different order, or occur any number of times (including zero times).

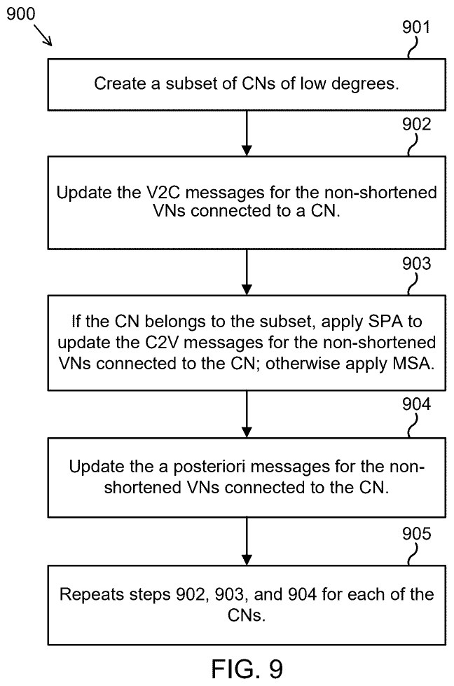

FIG. 7 illustrates a flowchart of an example procedure 700 for creating a subset of CNs to which SPA is applied based on degree of priority during an iteration of layered LDPC decoding according to embodiments of the present disclosure. For example, the procedure 700 for creating a subset of CNs employing SPA can be performed by the UE 116, the gNB 102, and/or network 130 in the wireless network 100 of FIG. 1. This example is for illustration only and other embodiments can be used without departing from the scope of the present disclosure. The example procedure 700 may be employed for step 601 of FIG. 6 or for step 901 of FIG. 9, to construct a subset [symbol] utilizing SPA.

The example procedure 700 of FIG. 7 begins with a set [symbol] containing all CNs being created (step 701). For the LDPC codes of dimension K and length N, there are (N−K) CNs and hence [symbol] ={0, 1, . . . , N−K−1}. The subset [symbol] composed of the CNs employing SPA is created and initialized to the empty set (step 702). A threshold value (or “priority threshold”) reflecting the number of edges involved in SPA is determined. The threshold value is denoted with d E {0, 1, . . . , D}, where D is a total number of edges in the Tanner graph. The threshold value is used to control the trade-off between performance and complexity in the layered decoding. A larger d leads to improved performance but increased complexity, and vice versa.

The degree of a CN is defined as the number of the VNs connected to that CN. Let wⱼ denote the degree of the CN j.

The CNs of the lowest degree in [symbol] are identified and form the set [symbol] ′, i.e., [symbol] ′={j:j∈ [symbol] and wⱼ=wₘᵢₙ}, where wₘᵢₙ=min{wⱼ:i∈ [symbol] } (step 703).

One of CNs from [symbol] ′ is added into [symbol] and then removed from [symbol] , i.e., [symbol] + [symbol] ← [symbol] ∪{j′} and [symbol] ← [symbol] \{j′}, where j′∈ [symbol] ′ (step 704) The removal prevents the occurrence of duplicate elements within B.

There may exist multiple CNs in [symbol] ′. Adding all CNs from [symbol] ′ into [symbol] at once may violate the threshold value. Therefore, the operations in steps 703 and 704 are repeated (step 705) to include CNs one-by-one into [symbol] until the summation of the degrees of CNs in the set [symbol] meets the threshold value. Given a threshold d, SPA can be applied to more layers by prioritizing the low-degree cNs such that performance degradation is mitigated.

Although FIG. 7 illustrates one example of a procedure 700 for creating a subset of CNs employing SPA during an iteration of layered LDPC decoding, various changes may be made to FIG. 7. For example, while shown as a series of steps, various steps in FIG. 7 could overlap, occur in parallel, occur in a different order, or occur any number of times (including zero times).

FIG. 8 illustrates a flowchart of an example procedure 800 for creating a subset of CNs to which SPA is applied based on degree of priority while consideration puncturing during an iteration of layered LDPC decoding according to embodiments of the present disclosure. For example, the alternative example procedure 800 for creating a subset of CNs employing SPA can be performed by the UE 116, the gNB 102, and/or network 130 in the wireless network 100 of FIG. 1. This example is for illustration only and other embodiments can be used without departing from the scope of the present disclosure. The alternative example procedure 800 may be employed for step 601 of FIG. 6 or for step 901 of FIG. 9, to construct a subset [symbol] utilizing SPA.

In LDPC codes, there may exist punctured VNs whose corresponding bits are not transmitted and for which a posteriori messages can be initialized to zeros for decoding. Let pⱼ denote the number of the punctured VNs connected to the CN j. In this embodiment, both the degrees of the CNs and the punctured VNs are utilized to construct [symbol] .

The example alternative procedure 800 of FIG. 8 begins with a set [symbol] containing all CNs being created (step 801). For the LDPC codes of dimension K and length N, there are N−K CNs and hence [symbol] ={0, 1, . . . , N−K−1}.

The set [symbol] composed of the CNs employing SPA is created and initialized to the empty set (step 802). A threshold value reflecting the number of edges involved in SPA is determined. The threshold value is denoted with d∈{0, 1, . . . , D}, where D is total number edges in the Tanner graph. The threshold value is used to control the trade-off between performance and complexity in the layered decoding. A larger d leads to improved performance but increased complexity, and vice versa.

The degree of a CN is defined as the number of the VNs connected to that CN. Let wⱼ denote the degree of the CN j.

The CNs of the lowest degree in [symbol] are identified and form the set [symbol] ′, i.e., [symbol] ′={j:j∈ [symbol] and wⱼ=wₘᵢₙ}, where wₘᵢₙ=min{wⱼ:i∈ [symbol] } (step 803).

From [symbol] ′, the CNs neighboring the largest number of punctured VNs are selected to form the set [symbol] ″⊆ [symbol] ′, that is [symbol] ″={j:j∈ [symbol] ′ and pⱼ=pₘₐₓ}, where pₘₐₓ=max{p:i∈ [symbol] ′}. One CN from [symbol] ″ is added into [symbol] and then removed from [symbol] , i.e., [symbol] ← [symbol] ∪{j′} and [symbol] + [symbol] \{j′}, where j′∈ [symbol] ″ (step 804). The removal prevents the occurrence of duplicate elements within [symbol] .

There may exist multiple CNs in [symbol] ″. Adding all CNs from [symbol] ″ into [symbol] at once may violate the threshold value. Therefore, the operations in steps 803 and 804 are repeated (step 805) to include CNs one-by-one into [symbol] until the summation of the degrees of CNs in the set [symbol] meets the threshold value. Given a threshold d, SPA can be applied to more layers by prioritizing the low-degree cNs and hence performance degradation is mitigated. Due to the lack of the channel observations, the punctured VNs are vulnerable to bit errors. Applying SPA, which offers accurate calculations of messages, to as many punctured VNs as possible further mitigates the performance degradation.

Although FIG. 8 illustrates one alternative example of a procedure 800 for creating a subset of CNs employing SPA during an iteration of layered LDPC decoding, various changes may be made to FIG. 8. For example, while shown as a series of steps, various steps in FIG. 8 could overlap, occur in parallel, occur in a different order, or occur any number of times (including zero times).

FIG. 9 illustrates a flowchart of an alternative example procedure 900 for performing an iteration of layered LDPC decoding selectively applying SPA and simplified SPA to check nodes while considering shortening according to embodiments of the present disclosure. For example, the alternative example procedure 900 for an iteration of layered LDPC decoding can be performed by the UE 116, the gNB 102, and/or network 130 in the wireless network 100 of FIG. 1. This example is for illustration only and other embodiments can be used without departing from the scope of the present disclosure.

For the sake of simplicity, FIG. 9 presents the operations concerning the message updates in one iteration, which can be generalized to other iterations. In LDPC codes, there may exist shortened VNs whose corresponding bits are fixed to zeros and known by the decoder. The bits corresponding to the shortening VNs may not be transmitted and for which a posteriori messages can be initialized to infinity for decoding. Let Sⱼ denote the set containing the shortened VNs connected to the CN j.

A subset, denoted [symbol] , of CNs is created (step 901), where SPA is used to calculate the C2V messages. In selecting CNs to form [symbol] , priority is given to those with fewer neighboring VNs by additionally considering shortening. By doing so, SPA can be applied to more CNs, meaning that MSA can be applied to fewer CNs, under the restriction of a fixed number of edges utilizing SPA. This allows for mitigation of performance degradation caused by the use of MSA. Embodiments of creating the set [symbol] are described below in connection with FIGS. 7, 8, 10, and 11: FIG. 7 discloses creating the set [symbol] based on degree of priority. FIG. 8 discloses creating the set [symbol] based on degree of priority and additionally considering puncturing. FIG. 10 discloses creating the set [symbol] based on degree of priority and considering shortening. FIG. 11 discloses creating the set B based on degree of priority and additionally considering both puncturing and shortening.

Since the updates of the C2V messages depend on the received V2C messages of small values, α_{i→j}=+∞ can be excluded from the calculations of β_{j→i}. In addition, the hard decisions at the shortened VNs are zeros, and therefore there is no need to update the messages regarding the shortened VNs. In one iteration of the layered decoding, CNs can be processed sequentially. Processing one of CNs j refers to the message updates according to steps 902, 903 and 904. However, the order of processing CNs is not limited in this disclosure.

Based on the latest γᵢ and β_{j→i}, the V2C messages passed from the non-shortened VNs neighboring the CN j to the CN j are updated (step 902) as follows:

$${α}_{i \to j} ← {γ}_{i} - {β}_{j \to i} for i ∈ {ℒ}_{j} ,$$

where [symbol] denotes the set of the VNs that are connected to the CN j and not shortened.

Based on the received V2C messages from the neighboring non-shortened VNs, the CN j updates the C2V messages (step 903) and passes those messages back to the neighboring non-shortened VNs. If the CN j belongs to [symbol] , SPA is applied; otherwise a simplified SPA, e.g., MSA, is used to compute the messages as follows:

$${β}_{j \to i} ← \{ \begin{matrix}2 \times tan {h}^{- 1} ( {\prod }_{{i}^{′} ∈ {ℒ}_{j \backslash i}} tan h ( \frac{{α}_{{i}^{′} \to j}}{2} ) ) , & i ∈ ℬ \\ ( {\prod }_{{i}^{′} ∈ {ℒ}_{j \backslash i}} sgn ( {α}_{{i}^{′} \to j} ) ) \times {min}_{{i}^{′} ∈ {ℒ}_{j ∖ i}} \vert {α}_{{i}^{′} \to j} \vert , & i ∉ {ℬ}^{c}\end{matrix} , for i ∈ {ℒ}_{j}$$

where [symbol] represents [symbol] excluding the VN i.

Based on the updated C2V messages from the CN j, the a posteriori messages for the non-shortened VNs [symbol] are updated (step 804) as follows:

$${γ}_{i} ← {α}_{i \to j} + {β}_{j \to i} for i ∈ {ℒ}_{j} .$$

The operations in steps 902, 903, and 904 are repeated for each of the CNs (step 905). The updated messages from the processing of current CN can be immediately applied to process next CN, which therefore speeds up convergence.

Although FIG. 9 illustrates one procedure 900 for an iteration of layered LDPC decoding, various changes may be made to FIG. 9. For example, while shown as a series of steps, various steps in FIG. 9 could overlap, occur in parallel, occur in a different order, or occur any number of times (including zero times).

FIG. 10 illustrates a flowchart of another alternative example procedure 1000 for creating a subset of CNs to which SPA is applied based on degree of priority during an iteration of layered LDPC decoding, with consideration of shortening, according to embodiments of the present disclosure. For example, the example procedure 1000 for creating a subset of CNs employing SPA can be performed by the UE 116, the gNB 102, and/or network 130 in the wireless network 100 of FIG. 1. This example is for illustration only and other embodiments can be used without departing from the scope of the present disclosure. The example procedure 1000 may be employed for step 601 of FIG. 6 or for step 901 of FIG. 9, to construct a subset [symbol] utilizing SPA.

In the embodiment of FIG. 10, both the degrees of the CNs and the shortened VNs are utilized to construct [symbol] . Let sⱼ denote the number of the shortened VNs which is connected to the CN j. In the procedure 1000 of FIG. 10, a set [symbol] containing all CNs is created (step 1001). For the LDPC codes of dimension K and length N, there are N−K CNs and hence [symbol] ={0, 1, . . . , N−K−1}.

Since the message updates corresponding to the shortened VNs can be removed, a metric for each of the CNs can be computed by considering the removal of the shortened VNs (step 1002). Let qⱼ denote the metric for the CN j. The value of qⱼ corresponds to the degree of the CN j minus the number of the shortened VNs connected to the CN j, that is qⱼ=wⱼ−sⱼ.

The set B composed of the CNs employing SPA is created and initialized to the empty set (step 1003). A threshold value reflecting the number of edges involved in SPA is determined. The threshold value is denoted with d∈{0,1, . . . , D}, where D is total number edges in the Tanner graph. The threshold value is used to control the trade-off between performance and complexity in the layered decoding. A larger d leads to improved performance but increased complexity, and vice versa.

The CNs of the smallest metric in A are identified and form the set A′, i.e., A′={j:j∈ [symbol] and qⱼ=qₘᵢₙ}, where qₘᵢₙ=min{qⱼ:i∈ [symbol] } (step 1004).

One of the CNs from [symbol] ′ is added into [symbol] and then removed from [symbol] , i.e., [symbol] ← [symbol] ∪{j′} and [symbol] ← [symbol] \{j′}, where j′∈ [symbol] ′ (step 1005). The removal prevents the occurrence of duplicate elements within [symbol] .

There may exist multiple CNs in [symbol] ′. Adding all CNs from [symbol] ′ into [symbol] at once may violate the threshold value. Therefore, the operations in steps 1004 and 1005 are repeated (step 1006) to include CNs one-by-one into [symbol] until the summation of the degrees of CNs in the set [symbol] meets the threshold value. Given a threshold d, SPA can be applied to more layers by prioritizing the low-degree cNs and hence performance degradation is mitigated.

Although FIG. 10 illustrates one alternative example of a procedure 1000 for creating a subset of CNs employing SPA during an iteration of layered LDPC decoding, various changes may be made to FIG. 10. For example, while shown as a series of steps, various steps in FIG. 10 could overlap, occur in parallel, occur in a different order, or occur any number of times (including zero times).

FIG. 11 illustrates a flowchart of still another alternative example procedure 1100 for creating a subset of CNs to which SPA is applied based on degree of priority during an iteration of layered LDPC decoding, with consideration of both shortening and puncturing, according to embodiments of the present disclosure. For example, the procedure 1100 for creating a subset of CNs employing SPA can be performed by the UE 116, the gNB 102, and/or network 130 in the wireless network 100 of FIG. 1. This example is for illustration only and other embodiments can be used without departing from the scope of the present disclosure. The procedure 1100 may be employed for step 601 of FIG. 6 or for step 901 of FIG. 9, to construct a subset [symbol] utilizing SPA.

In the embodiment of FIG. 11, the construction of [symbol] takes into account the degrees of the CNs, the punctured VNs, and the shortened VNs. A set [symbol] containing all CNs is created (step 1101). For the LDPC codes of dimension K and length N, there are N−K CNs and hence [symbol] ={0, 1, . . . , N−K−1}.

Since the message updates corresponding to the shortened VNs can be removed, a metric for each of the CNs can be computed by considering the removal of the shortened VNs (step 1102). Let qⱼ denote the metric for the CN j. The value of q, corresponds to the degree of the CN j minus the number of the shortened VNs connected to the CN j, that is qⱼ=wⱼ−sⱼ.

The set [symbol] composed of the CNs employing SPA is created and initialized to the empty set (step 1103). A threshold value reflecting the number of edges involved in SPA is determined. The threshold value is denoted with d∈{0,1, . . . , D}, where D is total number edges in the Tanner graph. The threshold value is used to control the trade-off between performance and complexity in layered decoding. A larger d leads to improved performance but increased complexity, and vice versa.

The CNs of the smallest metric in [symbol] are identified and form the set [symbol] ′, i.e., [symbol] ′={j:j∈ [symbol] and qⱼ=qₘᵢₙ}, where qₘᵢₙ=min{qⱼ:i∈ [symbol] } (step 1104).

From [symbol] ′, the CNs neighboring the largest number of punctured VNs are selected to form the set [symbol] ″⊆ [symbol] ′, that is [symbol] ″={j:j∈ [symbol] ′ and pⱼ=pₘₐₓ}, where pₘₐₓ=max{pⱼ:i∈ [symbol] ′} (step 1105). One CN from [symbol] ″ is added into [symbol] and then removed from [symbol] , i.e., [symbol] ← [symbol] ∪{j′} and [symbol] ← [symbol] \{j′}, where j′∈ [symbol] ″. The removal prevents the occurrence of duplicate elements within [symbol] .

There may exist multiple CNs in [symbol] ″. Adding all CNs from [symbol] ″ into [symbol] at once may violate the threshold value. Therefore, the operations in 1104 and 1105 are repeated to include CNs one-by-one into [symbol] until the summation of the degrees of CNs in the set [symbol] meets the threshold value (step 1106). Given a threshold d, SPA can be applied to more layers by prioritizing the low-degree cNs and hence performance degradation is mitigated. Due to the lack of the channel observations, the punctured VNs are vulnerable to bit errors. Applying SPA, which offers accurate calculations of messages, to as many punctured VNs as possible further mitigates performance degradation.

Although FIG. 11 illustrates one alternative example of a procedure 1100 for creating a subset of CNs employing SPA during an iteration of layered LDPC decoding, various changes may be made to FIG. 11. For example, while shown as a series of steps, various steps in FIG. 11 could overlap, occur in parallel, occur in a different order, or occur any number of times (including zero times).

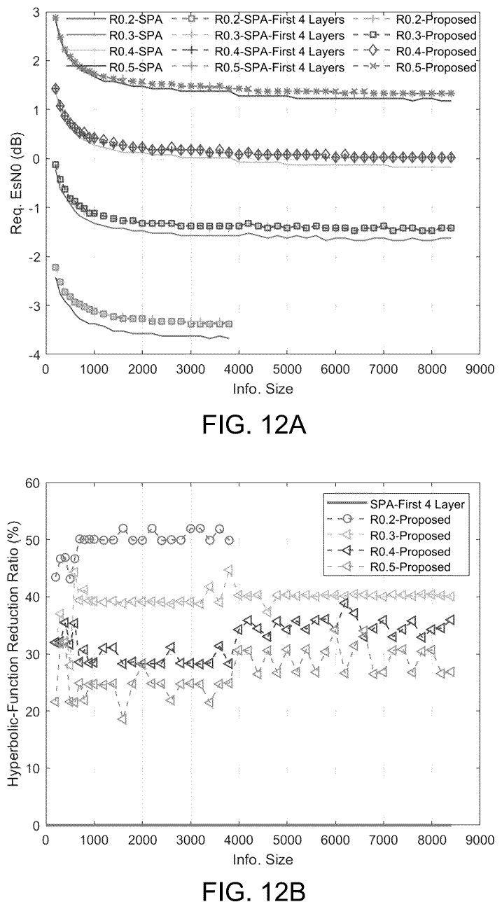

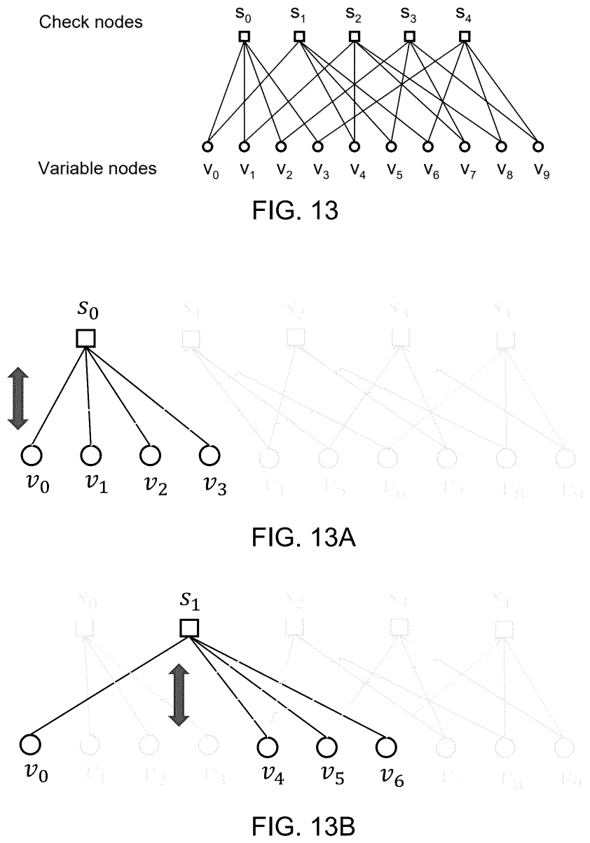

FIG. 12A illustrates comparisons between simulations of layered decoding of low-density parity check codes using only SPA and using a combination of SPA and MSA in accordance with the present disclosure, in terms of the required energy per symbol to noise power spectral density ratio (Es/N0) as a function of information size. The maximum number of iterations is 10, and the desired block error rate (BLER) is 10⁻². The traces labeled “SPA” in the legend apply SPA to all CNs; the traces labeled “First 4 Layer” apply SPA to the first four layers of the base graphs for those labeled “SPA”; and the traces labeled “Proposed” apply the approach described herein.

FIG. 12B illustrates simulations of the ratio of reduction in hyperbolic function, in percentage (%), as a function of information size achieved by selectively applying SPA and simplified SPA to check nodes according to embodiments of the present disclosure. The number of times of using hyberbolic functions is given by:

$${\sum }_{j ∈ {ℒ}_{SPA}} ( 3 {d}_{j} - 6 ) = 3 \times {\sum }_{j ∈ {ℒ}_{SPA}} {d}_{j} - 6 \times \vert {ℒ}_{SPA} \vert ,$$

where [symbol] denotes the set of CNs applying SPA and dⱼ denotes the degree of CN j. Given the total number of edges involved in SPA, i.e.,

$${\sum }_{j ∈ {ℒ}_{SPA}} {d}_{j} ,$$

as the number of the layers employing SPA (i.e., | [symbol] |) increases, more complexity reduction can be achieved. Selecting the CNs of low degrees in priority can include more layers employing SPA.

Any of the above variation embodiments can be utilized independently or in combination with at least one other variation embodiment. The above flowchart(s) illustrate example methods that can be implemented in accordance with the principles of the present disclosure and various changes could be made to the methods illustrated in the flowchart(s) herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the descriptions in this application should be read as implying that any particular element, step, or function is an essential element that must be included in the claims scope. The scope of patented subject matter is defined by the claims.

What is claimed is:

1. A method for decoding low-density parity check (LDPC) codes in a communication system, the method comprising:
selecting one or more of a plurality of check nodes (CNs) based on degree in priority, wherein a degree in priority for each of the plurality of CNs is based on a number of variable nodes (VNs) connected to the respective CN; and
performing layered decoding for a low-density parity-check (LDPC) code based on applying a sum-product algorithm and an approximated sum-product algorithm by:
applying the sum-product algorithm to at least some of the selected one or more CNs among the plurality of CNs; and
applying the approximated sum-product algorithm to one or more remaining CNs, other than the selected one or more CNs, among the plurality of CNs.

2. The method of claim 1, wherein the approximated sum-product algorithm includes a min-sum algorithm.

3. The method of claim 1, wherein selecting the one or more of the plurality of CNs based on degree in priority comprises:
selecting CNs among the plurality of CNs that have with low degrees in priority, wherein the low degree in priority is based on being less than a specified priority threshold.

4. The method of claim 3, wherein the specified priority threshold is a fixed number of edges involved in applying the sum-product algorithm.

5. The method of claim 1, wherein selecting the one or more of the plurality of CNs based on degree in priority comprises:
excluding shortened VNs before determining a degree in priority for each of the plurality of CNs.

6. The method of claim 5, wherein selecting the one or more of a plurality of check nodes (CNs) based on degree in priority comprises:
selecting, from among the plurality of CNs, at least one CN having a largest number of punctured VNs connected to the respective CN.

7. The method of claim 1, wherein selecting the one or more of a plurality of check nodes (CNs) based on degree in priority comprises:
selecting, from among the plurality of CNs, at least one CN having a largest number of punctured VNs connected to the respective CN.

8. An apparatus for decoding low-density parity check (LDPC) codes in a communication system, the apparatus comprising:
a transceiver configured to receive a signal having an associated LDPC code; and
at least one processor coupled to the transceiver and configured to decode the LDPC code by:
selecting one or more of a plurality of check nodes (CNs) based on degree in priority, wherein a degree in priority for each of the plurality of CNs is based on a number of variable nodes (VNs) connected to the respective CN; and
performing layered decoding for the LDPC code based on applying a sum-product algorithm and an approximated sum-product algorithm by:
applying the sum-product algorithm to at least some of the selected one or more CNs among the plurality of CNs; and
applying the approximated sum-product algorithm to one or more remaining CNs, other than the selected one or more CNs, among the plurality of CNs.

9. The apparatus of claim 8, wherein the approximated sum-product algorithm includes a min-sum algorithm.

10. The apparatus of claim 8, wherein the processor is configured to select the one or more of the plurality of CNs based on degree in priority by:
selecting CNs among the plurality of CNs that have with low degrees in priority, wherein the low degree in priority is based on being less than a specified priority threshold.

11. The apparatus of claim 10, wherein the specified priority threshold is a fixed number of edges involved in applying the sum-product algorithm.

12. The apparatus of claim 8, wherein the processor is configured to select the one or more of the plurality of CNs based on degree in priority by:
excluding shortened VNs before determining a degree in priority for each of the plurality of CNs.

13. The apparatus of claim 12, wherein the processor is configured to select the one or more of the plurality of CNs based on degree in priority by:
selecting, from among the plurality of CNs, at least one CN having a largest number of punctured VNs connected to the respective CN.

14. The apparatus of claim 8, wherein the processor is configured to select the one or more of the plurality of CNs based on degree in priority by:
selecting, from among the plurality of CNs, at least one CN having a largest number of punctured VNs connected to the respective CN.

15. A non-transitory machine readable medium comprising instructions that, when executed by at least one processor of an electronic device, cause the electronic device to decode low-density parity check (LDPC) codes in a communication system by:
selecting one or more of a plurality of check nodes (CNs) based on degree in priority, wherein a degree in priority for each of the plurality of CNs is based on a number of variable nodes (VNs) connected to the respective CN; and
performing layered decoding for the LDPC code based on applying a sum-product algorithm and an approximated sum-product algorithm by:
applying the sum-product algorithm to at least some of the selected one or more CNs among the plurality of CNs; and
applying the approximated sum-product algorithm to one or more remaining CNs, other than the selected one or more CNs, among the plurality of CNs.

16. The non-transitory machine readable medium of claim 15, wherein the approximated sum-product algorithm includes a min-sum algorithm.

17. The non-transitory machine readable medium of claim 15, wherein the instructions, when executed by at least one processor of an electronic device, cause the electronic device to select the one or more of the plurality of CNs based on degree in priority by:
selecting CNs among the plurality of CNs that have with low degrees in priority, wherein the low degree in priority is based on being less than a specified priority threshold.

18. The non-transitory machine readable medium of claim 17, wherein the specified priority threshold is a fixed number of edges involved in applying the sum-product algorithm.

19. The non-transitory machine readable medium of claim 15, wherein the instructions, when executed by the at least one processor of the electronic device, cause the electronic device to select the one or more of the plurality of CNs based on degree in priority by:
excluding shortened VNs before determining a degree in priority for each of the plurality of CNs.

20. The non-transitory machine readable medium of claim 15, wherein the instructions, when executed by the at least one processor of the electronic device, cause the electronic device to select the one or more of the plurality of CNs based on degree in priority by:
selecting, from among the plurality of CNs, at least one CN having a largest number of punctured VNs connected to the respective CN.
